(19) United States
(12) Patent Application Publication
(10) Pub. No.: US 2023/0343614 A1
(43) Pub. Date: Oct. 26, 2023

(54) SUBSTRATE PROCESSING APPARATUS, SUBSTRATE HOLDER, METHOD OF MANUFACTURING SEMICONDUCTOR DEVICE, AND RECORDING MEDIUM

(71) Applicant: Kokusai Electric Corporation, Tokyo (JP)

(72) Inventors: Shinya MORITA, Toyama-shi (JP); Seiyo NAKASHIMA, Toyama-shi (JP); Yoshitaka ABE, Toyama-shi (JP); Satoru MURATA, Toyama-shi (JP); Taisuke SAITO, Toyama-shi (JP)

(73) Assignee: Kokusai Electric Corporation, Tokyo (JP)

(21) Appl. No.: 18/337,549

(22) Filed: Jun. 20, 2023

Related U.S. Application Data
(63) Continuation of application No. PCT/JP2020/047756, filed on Dec. 21, 2020.

(51) Int. Cl. H01L 21/67; H01L 21/677

(52) U.S. Cl. CPC H01L 21/6719; H01L 21/67098; H01L 21/67248; H01L 21/67757

(57) ABSTRACT

There are provided a substrate holder that holds a plurality of substrates, a reaction tube that houses the substrate holder, a gas supplier that has a plurality of supply holes corresponding one-to-one to the plurality of substrates and supplies gas to the plurality of substrates, and a plurality of plates provided in substantially parallel to the plurality of substrates, in which at least part of each of the plurality of plates is disposed between the gas supplier and the substrate holder.

### CROSS-REFERENCE TO RELATED APPLICATIONS

This application is a Bypass Continuation Application of PCT International Application No. PCT/JP2020/047756, filed on Dec. 21, 2020, the entire contents of which are incorporated herein by reference.

### BACKGROUND

### Field

The present disclosure relates to a substrate processing apparatus, a substrate holder, a method of manufacturing a semiconductor device, and a recording medium.

### Description of the Related Art

There is a substrate processing apparatus that forms, with a substrate holder holding substrates on a multiple-stage basis in a processing furnace, a film on the surface of each substrate.

### SUMMARY

A substrate holder used in such a substrate processing apparatus as described above has a plate disposed between substrates in order to inhibit an ununiform flow of processing gas due to a prop, leading to an improvement in substrate in-plane uniformity.

However, such a conventional substrate processing apparatus has an inadequate rate of reach of processing gas supplied laterally to the substrate holder onto a wafer (inadequate efficiency of supply). Thus, there is room for improvement.

According to an embodiment of the present disclosure, there is provided a technology including:
a substrate holder that holds a plurality of substrates;
a reaction tube that houses the substrate holder;
a gas supplier that has a plurality of supply holes corresponding one-to-one to the plurality of substrates and supplies gas to the plurality of substrates; and
a plurality of plates provided in substantially parallel to the plurality of substrates, in which
at least part of each of the plurality of plates is disposed between the gas supplier and the substrate holder.

### BRIEF DESCRIPTION OF THE DRAWINGS

FIG. 1 illustrates a schematic configuration of a vertical processing furnace of a substrate processing apparatus favorably used in an embodiment of the present disclosure, in which a longitudinal sectional view of a processing furnace 202 is given.

FIG. 2 illustrates a schematic configuration of the vertical processing furnace of the substrate processing apparatus favorably used in the embodiment of the present disclosure, in which a section view of the processing furnace 202 taken along line A-A of FIG. 1 is given.

FIG. 3 is a perspective view of a substrate holder preferably used in the embodiment of the present disclosure.

FIG. 4A illustrates the positional relationship between a substrate held by the substrate holder preferably used in the embodiment of the present disclosure, a separation plate, and a gas supply hole. FIG. 4B is an enlarged view of part of FIG. 4A.

FIG. 5 is a horizontal sectional view illustrating the positional relationship between a substrate held by the substrate holder preferably used in the embodiment of the present disclosure, a separation plate, and a gas supply hole.

FIG. 6 illustrates a schematic configuration of a controller 121 of the substrate processing apparatus favorably used in the embodiment of the present disclosure with a block diagram of the control system of the controller 121.

FIG. 7 illustrates a sequence of processing favorably used in the embodiment of the present disclosure.

FIG. 8 is an explanatory view for a separation plate favorably used in a modified example of the embodiment of the present disclosure.

FIG. 9 is an explanatory view for a gas supplier favorably used in a modified example of the embodiment of the present disclosure.

FIG. 10 is an explanatory view for a separation plate favorably used in a modified example of the embodiment of the present disclosure.

FIG. 11 is an explanatory view for a separation plate favorably used in a modified example of the embodiment of the present disclosure.

FIG. 12 is an explanatory view for a separation plate favorably used in a modified example of the embodiment of the present disclosure.

FIG. 13 illustrates the positional relationship between a separation plate, a substrate, and a gas supply hole in FIG. 12.

FIG. 14 is an explanatory view for a separation plate favorably used in a modified example of the embodiment of the present disclosure.

### DETAILED DESCRIPTION

### Embodiment of the Present Disclosure

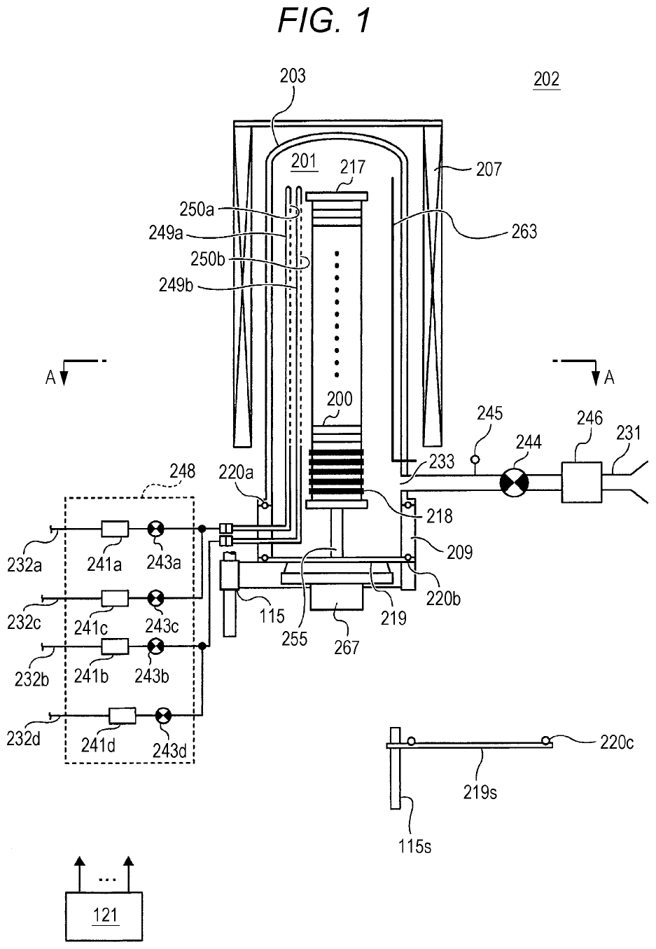

An embodiment of the present disclosure will be described below mainly with reference to FIGS. 1 to 7. Note that the drawings used in the following description are all schematic and thus, for example, the dimensional relationship between each constituent element and the ratio between each constituent element illustrated in the drawings do not necessarily coincide with realities. In addition, for example, a plurality of drawings does not necessarily coincide with each other in the dimensional relationship between each constituent element or in the ratio between each constituent element.

### (1) Configuration of Substrate Processing Apparatus

As illustrated in FIG. 1, a processing furnace 202 includes a heater 207 serving as a temperature regulator (heater). The heater 207 is cylindrical in shape and is vertically installed with support by a holding plate. The heater 207 further functions as an activator (exciter) that thermally activates (excites) gas.

Inside the heater 207, a reaction tube 203 is provided concentrically with the heater 207. The reaction tube 203 is formed of a heat-resistant material, such as quartz (SiO 2) or silicon carbide (SiC). The reaction tube 203 is cylindrical in shape with its upper end occluded and its lower end open, and has a tubular side face coaxial with a rotary shaft 255 described later, a top, and a space enclosed with the side face and the top. Below the reaction tube 203, a manifold 209 is provided concentrically with the reaction tube 203. The manifold 209 is formed of a metal material, such as stainless steel (SUS), and is cylindrical in shape with its upper end and lower end open. The manifold 209 has an upper end portion engaging with the lower end portion of the reaction tube 203 and thus supports the reaction tube 203. An O-ring 220a serving as a gasket is provided between the manifold 209 and the reaction tube 203. The reaction tube 203 is vertically installed, similarly to the heater 207. Mainly, with the reaction tube 203 and the manifold 209, a process container (reaction container) is achieved. The process container has a cylindrical hollow portion serving as a process chamber 201. The process chamber 201 is capable of housing a wafer 200 serving as a substrate. Processing is performed to such a wafer 200 in the process chamber 201.

In the process chamber 201, nozzles 249a and 249b serving, respectively, as first and second feeders are provided, in which the nozzles 249a and 249b penetrate through the side wall of the manifold 209. The nozzles 249a and 249b are also referred to as first and second nozzles, respectively. The nozzles 249a and 249b are each formed of a heat-resistant material, such as quartz or SiC. The nozzles 249a and 249b have, respectively, gas supply pipes 232a and 232b connected thereto. The nozzles 249a and 249b are independent from each other and are provided adjacently to each other.

The gas supply pipe 232a is provided with a mass flow controller (MFC) 241a serving as a flow rate controller and a valve 243a serving as an on/off valve in the order from the upstream side of a gas flow. The gas supply pipe 232b is provided with a mass flow controller (MFC) 241b serving as a flow rate controller and a valve 243b serving as an on/off valve in the order from the upstream side of a gas flow. A gas supply pipe 232c is connected to the downstream side of the valve 243a of the gas supply pipe 232a. A gas supply pipe 232d is connected to the downstream side of the valve 243b of the gas supply pipe 232b. The gas supply pipe 232c is provided with an MFC 241c and a valve 243c in the order from the upstream side of a gas flow. The gas supply pipe 232d is provided with an MFC 241d and a valve 243d in the order from the upstream side of a gas flow. The gas supply pipes 232a to 232d are each formed of a metal material, such as SUS.

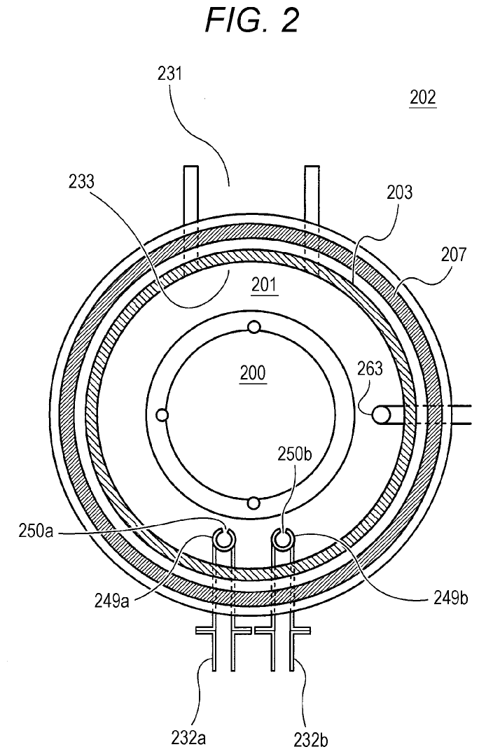

As illustrated in FIG. 2, the annular space in plan view between the inner wall of the reaction tube 203 and a wafer 200 is provided with the nozzles 249a and 249b each extending upward in the direction of an array of wafers 200 along the inner wall of the reaction tube 203 from the lower portion to upper portion of the inner wall. That is, the nozzles 249a and 249b are each provided, in a lateral region horizontally surrounding a wafer array region in which wafers 200 are arrayed, along the wafer array region. The nozzle 249a has a side face provided with a gas supply hole 250a serving as a supply hole for gas supply, and the nozzle 249b has a side face provided with a gas supply hole 250b serving as a supply hole for gas supply. The gas supply holes 250a and 250b are each open opposite (facing) an exhaust port 233 in plan view, enabling gas supply to the wafer 200. Such a plurality of gas supply holes 250a and a plurality of gas supply holes 250b are provided from the lower portion to upper portion of the reaction tube 203.

Source gas serving as processing gas is supplied from the gas supply pipe 232a into the process chamber 201 through the MFC 241a, the valve 243a, and the nozzle 249a.

Reactant gas serving as processing gas is supplied from the gas supply pipe 232b into the process chamber 201 through the MFC 241b, the valve 243b, and the nozzle 249b.

From the gas supply pipe 232c into the process chamber 201, an inert gas serving as processing gas is supplied through the MFC 241c, the valve 243c, the gas supply pipe 232a, and the nozzle 249a. From the gas supply pipe 232d into the process chamber 201, an inert gas serving as processing gas is supplied through the MFC 241d, the valve 243d, the gas supply pipe 232b, and the nozzle 249b.

For example, with the gas supply pipes 232a to 232d and the nozzles 249a and 249b, achieved is a gas supplier that supplies gas parallel to the surface of a wafer 200 to discharge the gas to the central axis.

Mainly, with the gas supply pipe 232a, the MFC 241a, and the valve 243a, a source-gas supply system is achieved. Mainly, with the gas supply pipe 232b, the MFC 241b, and the valve 243b, a reactant-gas supply system is achieved. Mainly, with the gas supply pipes 232c and 232d, the MFCs 241c and 241d, and the valves 243c and 243d, an inert-gas supply system is achieved.

Here, the source gas and the reactant gas act as film-forming gas and thus the source-gas supply system and the reactant-gas supply system can be referred to as a film-forming-gas supply system.

Any or all of the various supply systems described above may be provided as an integrated supply system 248 including, for example, the valves 243a to 243d and the MFCs 241a to 241d integrated. The integrated supply system 248 is connected to the gas supply pipes 232a to 232d such that a controller 121 described later controls the operations of supplying various types of gas into the gas supply pipes 232a to 232d, namely, the on/off operations of the valves 243a to 243d or the flow rate regulating operations with the MFCs 241a to 241d. The integrated supply system 248 is provided as a single integrated unit or a splittable integrated unit such that the integrated supply system 248 can be attached to or detached from the gas supply pipes 232a to 232d per integrated unit. Thus, for example, maintenance, replacement, or addition per integrated unit can be performed to the integrated supply system 248.

The side wall of the reaction tube 203 has a lower portion provided with the exhaust port 233 for exhausting the atmosphere in the process chamber 201. As illustrated in FIG. 2, in plan view, the exhaust port 233 is located opposite (facing) the nozzles 249a and 249b (gas supply holes 250a and 250b) across the wafer 200. The exhaust port 233 may be provided along the side wall of the reaction tube 203 from the lower portion to upper portion of the side wall, namely, along the wafer array region. The exhaust port 233 is in connection with an exhaust pipe 231. The exhaust pipe 231 is in connection with a vacuum pump 246 serving as a vacuum exhauster through a pressure sensor 245 serving as a pressure detector that detects the pressure in the process chamber 201 and an auto pressure controller (APC) valve 244 serving as a pressure regulator. With the vacuum pump 246 in operation, the APC valve 244 opens to vacuum-exhaust the process chamber 201 or shuts to stop the vacuum exhaust. Furthermore, with the vacuum pump 246 in operation, the APC valve 244 regulates its degree of valve opening, based on pressure information detected by the pressure sensor 245, so that the pressure in the process chamber 201 can be regulated. Mainly, with the exhaust pipe 231, the APC valve 244, and the pressure sensor 245, an exhaust system (gas exhauster) is achieved. The vacuum pump 246 may be included in the exhaust system.

Below the manifold 209, provided is a seal cap 219 serving as a furnace opening lid capable of hermetically occluding the opening at the lower end of the manifold 209. The seal cap 219 is formed of a metal material, such as SUS, and is discoid in shape. The seal cap 219 has an upper face provided with an O-ring 220b serving as a gasket that abuts on the lower end of the manifold 209. Below the seal cap 219, provided is a rotator 267 that rotates a boat 217 described later. The rotary shaft 255 of the rotator 267 penetrates through the seal cap 219 and is in connection with the boat 217. The rotator 267 rotates the boat 217 to rotate wafers 200. The seal cap 219 rises or falls vertically due to a boat elevator 115 serving as a lifter provided outside the reaction tube 203. The boat elevator 115 serves as a conveyer that raises or lowers the seal cap 219 to load (convey) wafers 200 into or unload (convey) the wafers 200 from the process chamber 201.

Below the manifold 209, provided is a shutter 219s serving as a furnace opening lid capable of hermetically occluding the opening at the lower end of the manifold 209 with the boat 217 unloaded from the process chamber 201 due to lowering of the seal cap 219. The shutter 219s is formed of a metal material, such as SUS, and is discoid in shape. The shutter 219s has an upper face provided with an O-ring 220c serving as a gasket that abuts on the lower end of the manifold 209. The on/off operation (e.g., lifting operation or turning operation) of the shutter 219s is controlled by a shutter on/off switch 115s.

The boat 217 serving as a substrate holder holds a plurality of wafers 200, such as 25 to 200 wafers 200, such that the wafers 200, of which the postures are kept horizontal and the centers are aligned, are arrayed vertically on a multiple-stage basis, namely, at intervals, though to be described in detail later. The boat 217 is formed of a heat-resistant material, such as quartz or SiC. The boat 217 has a lower portion at which heat insulating plates 218 formed of a heat-resistant material, such as quartz or SiC, are supported on a multiple-stage basis.

In the reaction tube 203, provided is a temperature sensor 263 serving as a temperature detector. The degree of energization to the heater 207 is regulated based on temperature information detected by the temperature sensor 263, so that the temperature in the process chamber 201 has a desired temperature distribution. The temperature sensor 263 is provided along the inner wall of the reaction tube 203.

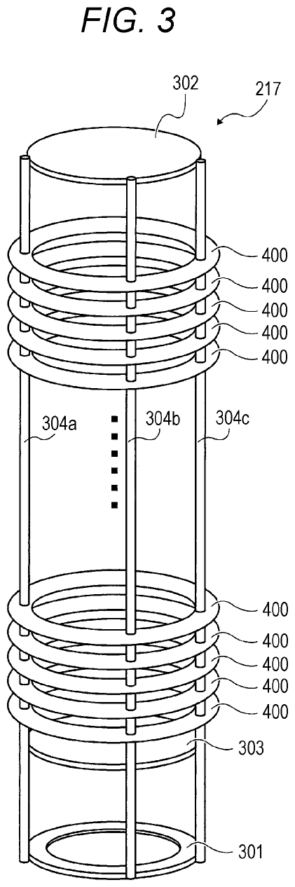

Next, the boat 217 will be described in detail with FIG. 3.

The boat 217 includes a bottom plate 301 ring-shaped, a top plate 302 discoid in shape, an intermediate plate 303 discoid in shape provided substantially horizontally between the bottom plate 301 and the top plate 302, and a plurality of props 304a to 304c (three props in the present embodiment) by which the bottom plate 301, the top plate 302, and the intermediate plate 303 are disposed in the vertical direction and are kept substantially horizontal.

The props 304a to 304c are provided with a plurality of separation plates 400 serving as a plurality of plates in the vertical direction between the top plate 302 and the intermediate plate 303, in which the plurality of separation plates 400 is kept substantially horizontal.

The plurality of separation plates 400 is each an annular flat plate and each is, for example, formed of quartz. Each separation plate 400 has an inner diameter not more than the outer diameter of a wafer 200 and has an outer diameter larger than the outer diameter of the wafer 200. In addition, the outer diameter of each separation plate 400 is larger than the diameter of a circle corresponding to the radius of gyration of the props 304a to 304c, namely, the diameter of the circumscribed circle 402 of the props 304a to 304c. Thus, part of each separation plate 400 is disposed outside the circumscribed circle 402.

The plurality of separation plates 400 is each fixed to the props 304a to 304c by substantially vertical penetration. That is, the plurality of separation plates 400 is each fixed due to the penetration of the props 304a to 304c, resulting in integration with the boat 217.

The plurality of separation plates 400 is each fixed to the props 304a to 304c of which the central axes are located inward by the amount equivalent to the diameter of each of the props 304a to 304c from the outer circumference of each separation plate 400 and are located outside the inner circumference of each separation plate 400. Thus, each separation plate 400 protrudes by a predetermined amount or more outside the circumscribed circle 402 of the props 304a to 304c, such as by an amount not less than the radius of each of the props 304a to 304c, in other words, by an amount not less than half the width of each of the props 304a to 304c.

Between each separation plate 400, provided is a support pin 221 serving as a support for holding a wafer 200 substantially horizontally. From each of the plurality of props 304a to 304c, such support pins 221 extend inward, substantially horizontally, such that a wafer 200 is supported at predetermined intervals (pitches) between an upper separation plate 400 and a lower separation plate 400. Each support pin 221 is not limited to a projection shaped like a rod and thus may be a semicircular projection formed by cutting off parts not for the support pin 221 from a round rod for the material of the props 304a to 304c.

Next, the positional relationship between gas supply holes 250a and 250b, a separation plate 400, and a wafer 200 will be described in detail.

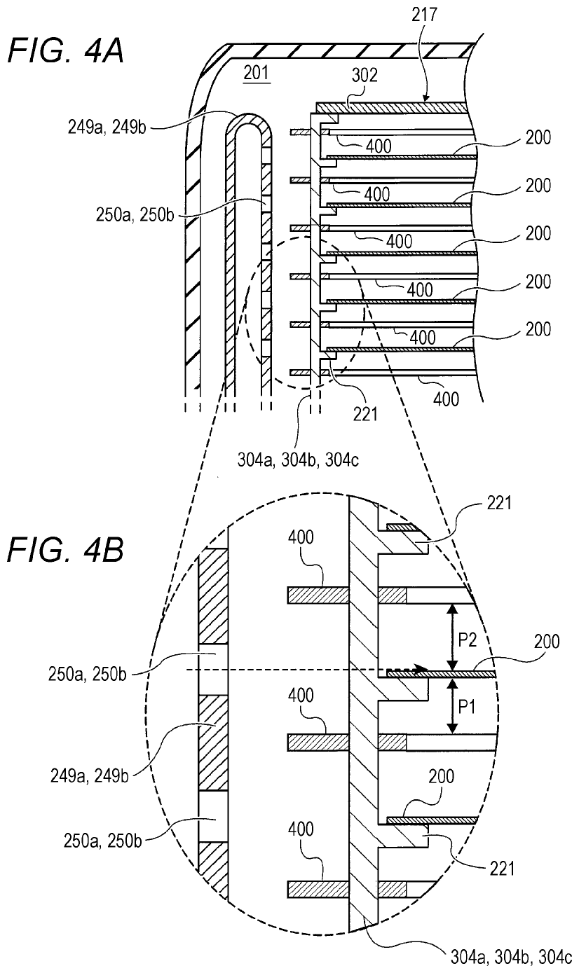

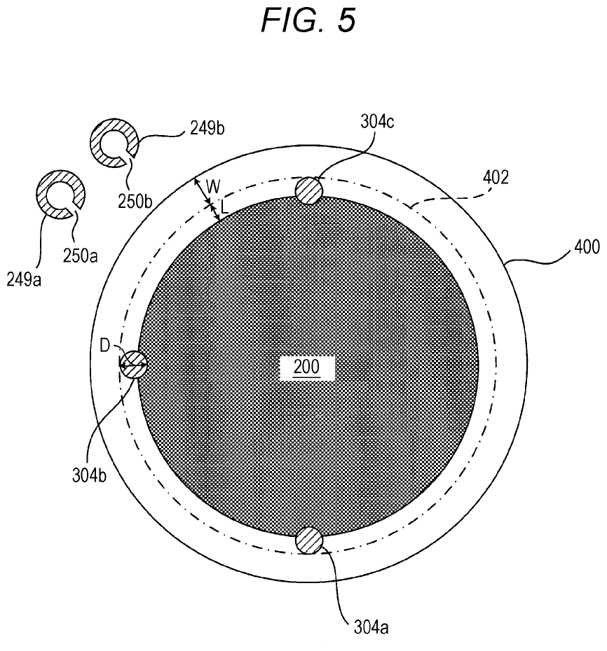

FIG. 4A is a partial enlarged view of the vicinity of the nozzles 249a and 249b in the process chamber 201. FIG. 4B is a partial enlarged view of the vicinity of gas supply holes 250a and 250b illustrated in FIG. 4A. FIG. 5 is a horizontal sectional view illustrating the positional relationship between gas supply holes 250a and 250b, a separation plate 400, and a wafer 200.

The plurality of separation plates 400 is each disposed between gas supply holes 250a in the up-down direction of the gas supply holes 250a and between gas supply holes 250b in the up-down direction of the gas supply holes 250b. Preferably, the plurality of separation plates 400 is disposed one-to-one between the top plate 302 and a wafer 200, between each wafer 200, and between a wafer 200 and the intermediate plate 303, in substantially parallel to the wafers 200. Part of each of the plurality of separation plates 400 is disposed in the space between the nozzles 249a and 249b and the boat 217. Such a configuration enables inhibition of a flow of gas in a substantially vertical direction between the nozzles 249a and 249b and the boat 217 and in the up-down direction.

At the position between each of the plurality of separation plates 400, three support pins 221 hold a wafer 200 substantially horizontally. That is, a plurality of support pins 221 holds a plurality of wafers 200 at predetermined pitches such that each wafer 200 is located between separation plates 400. The distance P1 between each wafer 200 and the lower adjacent separation plate 400 and the distance P2 between each wafer 200 and the upper adjacent separation plate 400 are determined in accordance with the type of the end effector of a transferer.

As an example, as illustrated in FIG. 4B, the plurality of separation plates 400 is each disposed, between the upper adjacent wafer 200 serving as a wafer corresponding to the separation plate 400 and the lower adjacent wafer 200 serving as a wafer corresponding to the separation plate 400, closer to the upper adjacent wafer 200 in height than to the lower adjacent wafer 200. That is, each separation plate 400 is provided such that the distance P2 to the lower adjacent wafer 200 is longer than the distance P1 to the upper adjacent wafer 200. Such a configuration enables an adequate interval between a wafer 200 and the upper separation plate 400 to the wafer 200 and thus is favorable to a suction or Bernoulli's end effector. Alternatively, according to a configuration in which the distance P1 is larger than the distance P2, below a wafer 200, a space for insertion of the end effector of a transferer that bears and conveys the wafer 200 is ensured and a space for lifting and conveying the wafer 200 is ensured above the wafer 200.

Between upper and lower adjacent separation plates 400, the respective upper ends and lower ends of a gas supply hole 250a and a gas supply hole 250b are disposed. Between the respective upper ends and lower ends of the gas supply hole 250a and the gas supply hole 250b, a wafer 200 is disposed almost at the centers of the gas supply hole 250a and the gas supply hole 250b. That is, the plurality of gas supply holes 250a is each disposed corresponding to the position of the wafer 200 between the corresponding separation plates 400 and the plurality of gas supply holes 250b is each disposed corresponding to the position of the wafer 200 between the corresponding separation plates 400. Then, gas is supplied from each gas supply hole 250a to the corresponding wafer 200 and gas is supplied from each gas supply hole 250b to the corresponding wafer 200, followed by formation of a parallel flow of gas on the surface of each wafer 200, resulting in efficient gas supply to each of the plurality of wafers 200.

Note that the plurality of separation plates 400 is each annular as described above and each has an opening at its center. That is, the space between upper and lower wafers 200 is not completely separated. Thus, the pitch between wafers can be kept wide, so that gas flows easily on a wafer 200 without detouring around the wafer 200. At a central portion, which causes a film thin in thickness, in a wafer, a flow channel has its height increasing to the interval between wafers, enabling prevention of a reduction in flow velocity and supply of unreacted gas through the opening at the center of a separation plate 400.

Specifically, the inflow of gas from the gas supply holes 250a and 250b corresponding to a wafer 200 branches into two flows of gas that are a flow of gas between the upper side of the corresponding wafer 200 and the separation plate 400 directly above the wafer 200 and a flow of gas between the lower side of the corresponding wafer 200 and the separation plate 400 right below the wafer 200. Then, the upper flow of gas merges, at the opening at the center of the upper separation plate 400, with a flow of gas to the upper adjacent wafer 200 to the corresponding wafer, and the lower flow of gas merges, at the opening at the center of the lower separation plate 400, with a flow of gas to the lower adjacent wafer 200 to the corresponding wafer.

According to such a configuration, the gas supplied from gas supply holes 250a and 250b causes an increase in the quantity of gas flowing between wafers 200, leading to an increase in the gas inflow rate that is the rate at which the gas supplied from gas supply holes 250a and 250b flows between wafers 200. Use of a separation plate 400 enables a smaller surface area and less gas consumption than use of a discoid separation plate.

In the process chamber 201, the plurality of separation plates 400 is fixed and arrayed at predetermined intervals (pitches) by the props 304a to 304c, orthogonally to the rotary shaft 255 and concentrically with the rotary shaft 255. That is, the center of each separation plate 400 is aligned with the central axis of the boat 217. In addition, the central axis of the boat 217 coincides with the central axis of the reaction tube 203 and the rotary shaft 255. That is, the plurality of separation plates 400 is supported at constant intervals by the props 304a to 304c of the boat 217 with their postures kept horizontal and their centers aligned with each other, in which the stack direction corresponds to the axial direction of the reaction tube 203. That is, the boat 217 including the plurality of separation plates 400 is housed rotatably in the reaction tube 203.

Each of the plurality of separation plates 400 has, as illustrated in FIG. 5, a width W occupying between the nozzles 249a and 249b and the circumscribed circle 402 that is a circle corresponding to the radius of gyration of the props 304a to 304c in horizontal sectional view, larger than the width of each of the props 304a to 304c of the boat 217 (diameter D of each of the props 304a to 304c in FIG. 5) or the distance L between the circumscribed circle 402 and the end portion of the wafer 200.

That is, at least part of each of the plurality of separation plates 400 is disposed outside the circumscribed circle 402 of the props 304a to 304c in the space between the nozzles 249a and 249b and the boat 217, and the plurality of separation plates 400 is fixed to the props 304a to 304c, in substantially parallel with the plurality of wafers 200.

According to such a configuration, each separation plate 400 protrudes by a predetermined amount or more outside the props 304a to 304c, enabling inhibition of a flow of gas in a substantially vertical direction between the nozzles 249a and 249b and the boat 217 and in the up-down direction. Therefore, a reduction can be made in loading effect with an improvement in the efficiency of gas supply to each wafer 200. In particular, the gas supplied from the gas supply holes 250a and 250b can be inhibited from flowing down due to hitting against the props 304a to 304c.

This results in an increase in the inflow rate of gas onto each wafer 200, so that constancy or improvement can be achieved in in-plane uniformity. An improvement can be made in inter-plane uniformity with inhibition of diffusion in the up-down direction of each wafer 200.

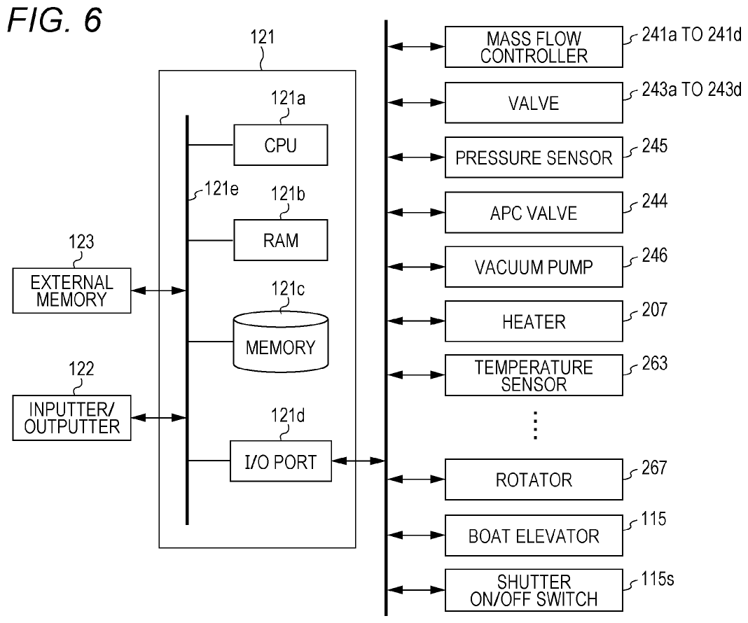

As illustrated in FIG. 6, a controller 121 serves as a computer including a central processing unit (CPU) 121a, a random access memory (RAM) 121b, a memory 121c, and an I/O port 121d. The RAM 121b, the memory 121c, and the I/O port 121d are capable of data exchange with the CPU 121a through an internal bus 121e. An input/output device 122 serving, for example, as a touch panel is connected to the controller 121.

The memory 121c is achieved, for example, with a flash memory, a hard disk drive (HDD), or a solid state drive (SSD). In the memory 121c, readably stored are a control program for controlling the operation of the substrate processing apparatus and a process recipe including procedures of substrate processing and conditions therefor described later. The process recipe functions as a program that causes the controller 121 to perform each procedure in substrate processing described later to obtain a predetermined result. Hereinafter, the process recipe and the control program are also collectively and simply referred to as a program. The process recipe is also simply referred to as a recipe. In the present specification, in some cases, the term “program” indicates only the recipe, only the control program, or both of the recipe and the control program. The RAM 121b serves as a memory area (work area) in which the program or data read by the CPU 121a is temporarily stored.

The I/O port 121d is connected to, for example, the MFC 241a to 241d, the valves 243a to 243d, the pressure sensor 245, the APC valve 244, the vacuum pump 246, the temperature sensor 263, the heater 207, the rotator 267, the boat elevator 115, and the shutter on/off switch 115s described above.

The CPU 121a is capable of reading the control program from the memory 121c to execute the control program and reading the recipe from the memory 121c in response to an operation command input through the input/output device 122. In accordance with the content of the read recipe, the CPU 121a is capable of controlling the flow rate regulating operations of various types of gas with the MFC 241a to 241d, the on/off operations of the valves 243a to 243d, the on/off operation of the APC valve 244, the pressure regulating operation with the APC valve 244 based on the pressure sensor 245, the startup or shutdown of the vacuum pump 246, the temperature regulating operation of the heater 207 based on the temperature sensor 263, the rotation of the boat 217 with the rotator 267 and the rotational rate regulating operation of the rotator 267, the lifting operation of the boat 217 with the boat elevator 115, and the on/off operation of the shutter 219s with the shutter on/off switch 115s.

The controller 121 can be achieved due to installation of the above program stored in an external memory 123 into the computer. Examples of the external memory 123 include a magnetic disk, such as an HDD, an optical disc, such as a CD, a magneto-optical disc, such as an MO, and a semiconductor memory, such as a USB memory or an SSD. The memory 121c and the external memory 123 each serve as a computer-readable recording medium. Hereinafter, such memories are collectively and simply referred to as a recording medium. In the present specification, in some cases, the term “recording medium” indicates only the memory 121c, only the external memory 123, or both thereof. Note that the program may be provided to the computer, for example, through the internet or a dedicated line, instead of the external memory 123.

### (2) Substrate Processing Process

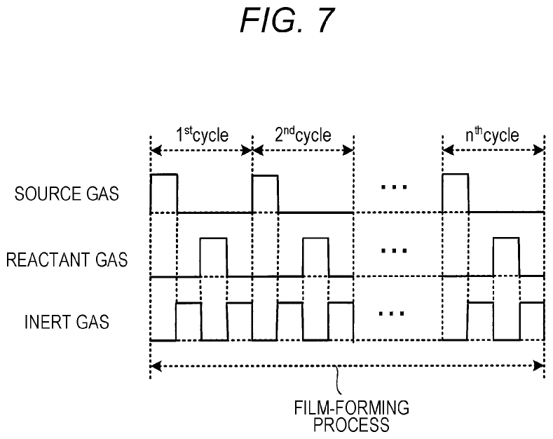

An exemplary sequence of substrate processing of forming a film on the surface of a wafer 200 serving as a substrate will be described mainly with FIG. 7 as a partial process in the process of manufacturing a semiconductor device with the substrate processing apparatus described above. In the following description, the controller 121 controls the operation of each constituent of the substrate processing apparatus.

In the present specification, in some cases, the term “wafer” means a wafer itself, or means a laminate of a wafer and a predetermined layer or film formed on the surface of the wafer. In the present specification, in some cases, the term “surface of a wafer” means the surface of a wafer itself or means the surface of a predetermined layer or the like formed on a wafer. In the present specification, in some cases, the expression “form a predetermined layer on a wafer” means that directly form a predetermined layer on the surface of a wafer itself or means that form a predetermined layer on a layer or the like formed on a wafer. In the present specification, the term “substrate” is synonymous with the term “wafer”.

### Wafer Charge and Boat Load

When a plurality of wafers 200 is charged to the boat 217 (wafer charge), the shutter on/off switch 115s moves the shutter 219s, so that the opening at the lower end of the manifold 209 is exposed (shutter open). After that, as illustrated in FIG. 1, the boat elevator 115 lifts up the boat 217 supporting the plurality of wafers 200, to load the boat 217 into the process chamber 201 (boat load), so that the plurality of wafers 200 is housed in the process chamber 201. In this state, the lower end of the manifold 209 is sealed by the seal cap 219 through the O-ring 220b.

### Pressure Regulation and Temperature Regulation

After that, the vacuum pump 246 performs vacuum exhaust (decompression exhaust) such that the process chamber 201 has its inside, namely, the space in which the wafers 200 are present, at a desired pressure (desired degree of vacuum). In this case, the pressure sensor 245 measures the pressure in the process chamber 201 and then the APC valve 244 is feedback-controlled based on information on the measured pressure. The heater 207 performs heating such that the wafers 200 in the process chamber 201 have a desired process temperature. In this case, based on information on the temperature detected by the temperature sensor 263, the degree of energization to the heater 207 is feedback-controlled such that a desired temperature distribution is acquired in the process chamber 201. The rotator 267 starts to rotate the wafers 200. The exhaust in the process chamber 201, the heating to the wafers 200, and the rotation of the wafers 200 each continue at least until the processing to the wafers 200 finishes.

### Film-Forming Process

After that, the following first to fourth steps are performed in this order. Each step will be described below.

### First Step (Source Gas Supply)

The valve 243a is opened to supply source gas into the gas supply pipe 232a. The source gas is supplied into the process chamber 201 through the nozzle 249a while being regulated in flow rate by the MFC 241a and then is exhausted through the exhaust port 233. In this case, the source gas is supplied to the surface of each wafer 200 (source gas supply). In this case, the valves 243c and 243d may be opened to supply inert gases, such as nitrogen (N 2), into the process chamber 201 through the nozzles 249a and 249b, respectively.

The supply of the source gas to the surface of each wafer 200 causes, on the surface of each wafer 200, formation of a first layer including an element contained in the source gas.

As the source gas, for example, an Si-and-halogen containing gas can be used. Halogen includes, for example, chlorine (Cl), fluorine (F), bromine (Br), and iodine (I).

### Second Step (Purge)

After the elapse of a predetermined time from the start of supply of the source gas, the valve 243a is shut to stop the supply of the source gas. In this case, with the exhaust pipe 231 having the APC valve 244 opened, the vacuum pump 246 vacuum-exhausts the process chamber 201 to remove the residual gas on each wafer 200, so that the unreacted source gas remaining in the process chamber 201 is eliminated (exhausted) from the process chamber 201 (purge). In this case, the valves 243c and 243d are opened to supply inert gases serving as purge gas into the process chamber 201. The inert gases act as purge gas to remove the residual gas from the surface of each wafer 200, resulting in an enhancement in the effect of eliminating, from the process chamber 201, the unreacted source gas remaining in the process chamber 201.

### Third Step (Reactant Gas Supply)

After the elapse of a predetermined time from the start of the purge, the valve 243b is opened to supply reactant gas into the gas supply pipe 232b. The reactant gas is supplied into the process chamber 201 through the nozzle 249b while being regulated in flow rate by the MFC 241b and then is exhausted through the exhaust port 233. In this case, the reactant gas is supplied to the surface of each wafer 200 (reactant gas supply). In this case, the valves 243c and 243d may be opened to supply inert gases into the process chamber 201 through the nozzles 249a and 249b, respectively.

The supply of the reactant gas to the surface of each wafer 200 enables reaction of at least part of the first layer formed on the surface of each wafer 200. Thus, a second layer resulting from reaction of the first layer is formed on the surface of each wafer 200.

As the reactant gas, a gas that reacts with the source gas is used. Note that, for formation of a film such as an oxide film, an oxidation gas containing oxygen (O) can be used as the reactant gas. For formation of a film such as a nitride film, a nitridation gas containing nitrogen (N) can be used as the reactant gas.

### Fourth Step (Purge)

After the elapse of a predetermined time from the start of supply of the reactant gas, the valve 243b is shut to stop the supply of the reactant gas. Then, based on a processing procedure and processing conditions similar to those for the purge in the second step, for example, the gas remaining in the process chamber 201 is eliminated (exhausted) from the process chamber 201 (purge).

### Predetermined Number of Times of Performance

A cycle in which the first to fourth steps described above are performed not simultaneously, namely, asynchronously, is repeated a predetermined number of times (n times: n is an integer of one or more) to form a film having a predetermined thickness on the surface of each wafer 200. Preferably, the cycle described above is repeated a plurality of times. That is, preferably, the cycle described above is repeated a plurality of times until a film has a desired thickness due to a stack of second layers, in which the thickness of the second layer formed per single cycle is smaller than the desired thickness.

### After-Purge and Atmospheric Pressure Restoration

Respective inert gases through the nozzles 249a and 249b are supplied into the process chamber 201 and then are exhausted through the exhaust port 233. The inert gases supplied through the nozzles 249a and 249b act as purge gas. Thus, a purge is conducted in the process chamber 201, so that the residual gas and any reaction by-product in the process chamber 201 are removed from the process chamber 201 (after-purge). After that, the atmosphere in the process chamber 201 is replaced with the inert gases (Inert gas replacement), so that the pressure in the process chamber 201 is restored to the normal pressure (atmospheric pressure restoration).

### Boat Unload and Wafer Discharge

After that, the boat elevator 115 lowers the seal cap 219, resulting in exposure of the opening at the lower end of the manifold 209. Then, the processed wafers 200 that the boat 217 has supported are unloaded outward from the reaction tube 203 through the lower end of the manifold 209 (boat unload). After the boat unload, the shutter 219s is moved, so that the opening at the lower end of the manifold 209 is sealed with the shutter 219s through the O-ring 220c (shutter close). After being unloaded outward from the reaction tube 203, the processed wafers 200 are taken out from the boat 217 (wafer discharge).

### (3) Modified Examples

The separation plates 400 or the gas supplier in the embodiment described above can be modified as in the following modified examples. Unless otherwise specified, the configuration in each modified example is similar to the configuration in the embodiment described above, and thus the description thereof will be omitted.

### Modified Example 1

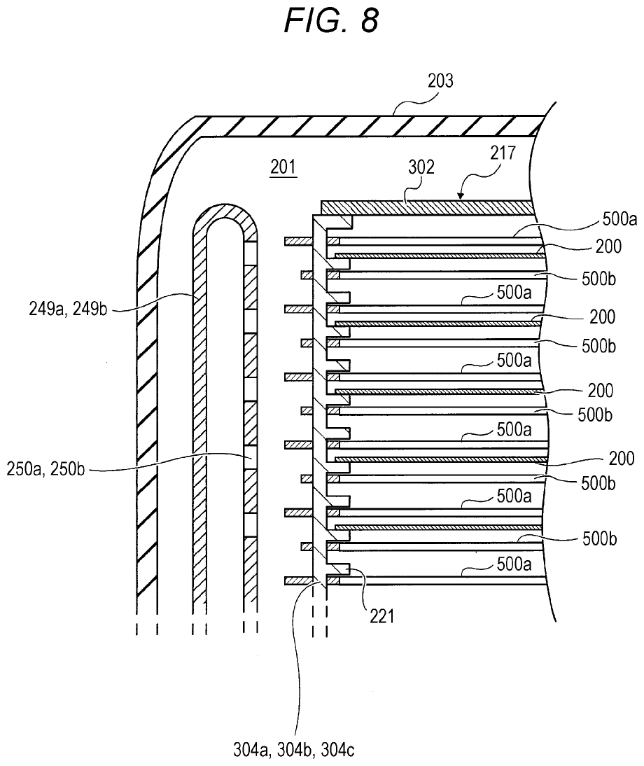

In Modified Example 1, as a plurality of separation plates, as illustrated in FIG. 8, separation plates 500a large in diameter and separation plates 500b small in diameter are used, instead of the separation plates 400 identical in diameter in the embodiment described above. The separation plates 500a large in diameter and the separation plates 500b small in diameter are different in outer diameter but are identical in inner diameter. The separation plates 500a and the separation plates 500b are disposed in substantially parallel to wafers 200, in which part of each separation plate 500a and part of each separation plate 500b are disposed in the space between nozzles 249a and 249b and a boat 217.

That is, the separation plates 500a annular in shape and large in diameter and the separation plates 500b annular in shape and small in diameter are alternately disposed in the vertical direction and are fixed to props 304a to 304c. Then, the wafers 200 are each placed on support pins 221 disposed directly above a separation plate 500b small in diameter. That is, the wafers 200 are not placed on support pins 221 disposed directly above any separation plate 500a large in diameter. In other words, each separation plate 500b small in diameter is adjacent above to the corresponding separation plate 500a large in diameter. Each wafer 200 is adjacent above to the corresponding separation plate 500b small in diameter. Each separation plate 500a large in diameter is adjacent above to the corresponding wafer 200. The upper end and lower end of each of gas supply holes 250a and 250b are disposed corresponding to the position of the wafer 200 between the corresponding separation plate 500a large in diameter and the corresponding separation plate 500b small in diameter.

The separation plates 500a large in diameter each adjacent above to the wafer 200 and the separation plates 500b small in diameter each adjacent below to the wafer 200 enable, with rectification of a flow of gas, suppression of the quantity of gas consumption due to the separation plates 500a and 500b. Regulation of the width W of each separation plate 500a and the width W of each separation plate 500b disposed outside the circumscribed circle 402 of the props 304a to 304c enables an improvement in in-plane uniformity and an improvement in inter-plane uniformity with inhibition of a change in the thickness of a film at the end portion of each wafer 200 or near the props 304a to 304c.

Note that the configuration in which the separation plates 500b small in diameter are annular in shape has been given above, but this is not limiting. Thus, the separation plates 500b small in diameter may be discoid in shape or may be C-shaped. Alternatively, provided may be crescent-shaped or arc-shaped plates fixed to each of the props 304a to 304c. The arrangement positions of the separation plates 500a large in diameter and the arrangement positions of the separation plates 500b small in diameter may be changed with each other. Even in such a case, an effect similar to that in the present Modified Example 1 can be obtained.

### Modified Example 2

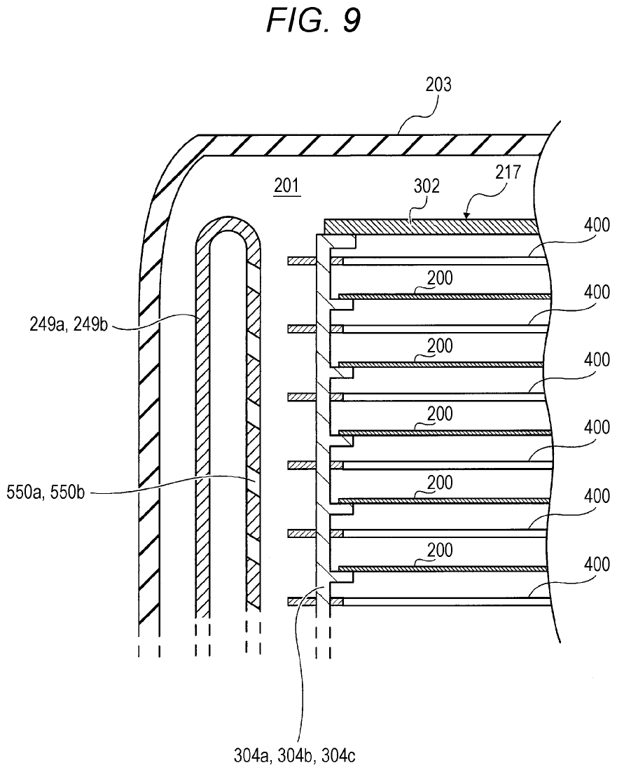

In Modified Example 2, as a gas supplier, as illustrated in FIG. 9, a nozzle 249a having gas supply holes 550a open obliquely and a nozzle 249b having gas supply holes 550b open obliquely are used, instead of the nozzle 249a having the gas supply holes 250a open substantially horizontally and the nozzle 249b having the gas supply holes 250b open substantially horizontally in the embodiment described above.

That is, the gas supply holes 550a and 550b are each directed obliquely downward. That is, the gas supply holes 550a and 550b each supply gas to the surface of a wafer 200 from obliquely above. The gas supply holes 550a and 550b are each disposed corresponding to the position of the wafer between separation plates 400. Specifically, the upper end and lower end of each of the gas supply holes 550a and 550b are disposed between the upper face of the corresponding wafer 200 and the separation plate 400 adjacent above to the corresponding wafer 200. According to such a configuration, the gas supplied obliquely downward from each of the gas supply holes 550a and 550b is supplied to the upper face of the corresponding wafer 200, efficiently. The gas supplied to the lower face of the corresponding wafer 200 reflects off the separation plate 400 adjacent below to the corresponding wafer 200 and then is supplied to the lower adjacent wafer 200 through the opening at the center of the separation plate 400. Thus, a flow of gas between each separation plate 400 can be regulated, leading to efficient gas supply to each wafer 200. An improvement in in-plane uniformity and an improvement in inter-plane uniformity can be made with inhibition of a change in the thickness of a film at the end portion of each wafer 200 or near props 304a to 304c.

Note that the configuration in which the gas supply holes 550a and 550b are each directed obliquely downward has been given above, but this is not limiting. Thus, the gas supply holes 550a and 550b may be each directed obliquely upward. That is, the gas supply holes 550a and 550b may each supply gas to the surface of the corresponding wafer 200 from obliquely below. According to such a configuration, the gas supplied obliquely upward from each of the gas supply holes 550a and 550b reflects off the separation plate 400 adjacent above to the corresponding wafer 200 and then is supplied to the upper face of the corresponding wafer 200. Even in such a case, an effect similar to that in the present Modified Example 2 can be obtained.

### Modified Example 3

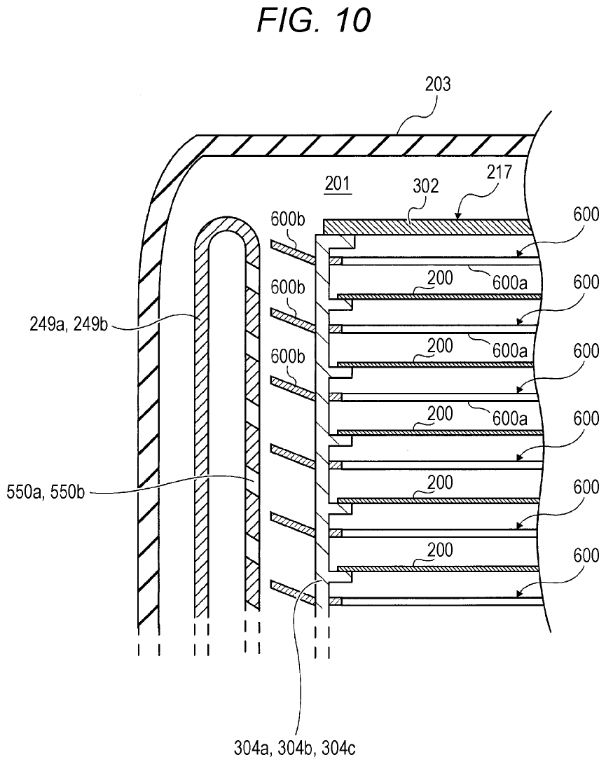

In Modified Example 3, as illustrated in FIG. 10, in addition to the nozzle 249a having the gas supply holes 550a and the nozzle 249b having the gas supply holes 550b in Modified Example 2 described above as a gas supplier, separation plates 600 are used, instead of the separation plates 400. The separation plates 600 each include a central portion 600a annular in shape disposed inside props 304a to 304c and an outer circumferential portion 600b disposed outside the props 304a to 304c. The outer circumferential portion 600b is angled obliquely upward with respect to the central portion 600a and is directed obliquely upward. That is, the respective outer circumferential portions 600b of the separation plates 600 are disposed in the space between the nozzles 249a and 249b and a boat 217 and the respective central portions 600a of the separation plates 600 are disposed in substantially parallel to wafers 200.

That is, the gas supply holes 550a and 550b are each directed obliquely downward and supply gas to the surface of the corresponding wafer 200 from obliquely above, similarly to Modified Example 2 described above. Then, the upper end and lower end of each of the gas supply holes 550a and 550b are disposed corresponding to the position of the wafer 200 between the outer circumferential portions 600b of separation plates 600. Thus, a flow of gas between each separation plate 600 can be regulated, leading to efficient gas supply to each wafer 200. A thicker film can be inhibited from being formed at the end portion of each wafer 200, so that an improvement can be made in in-plane uniformity. Note that, even in a case where, instead of the gas supply holes 550a and 550b, the nozzle 249a having the gas supply holes 250a open substantially horizontally and the nozzle 249b having the gas supply holes 250b open substantially horizontally described above are used, an effect similar to that in the present Modified Example 3 can be obtained.

### Modified Example 4

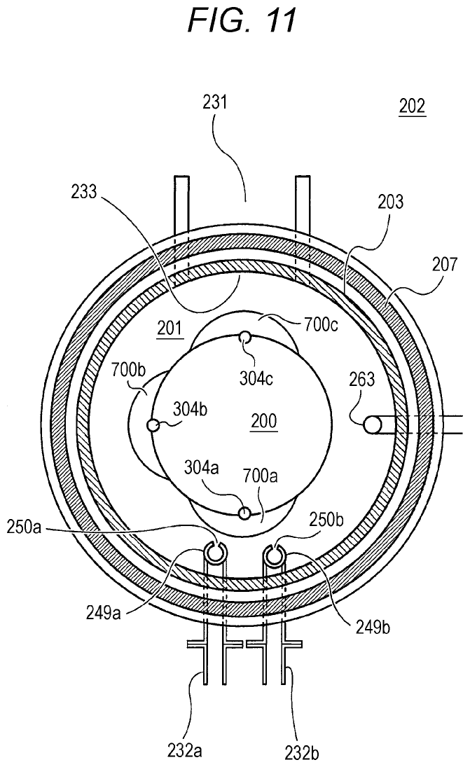

In Modified Example 4, as a separation plate, as illustrated in FIG. 11, separation plates 700a to 700c of one or more crescent-shaped plates (three in the present Modified Example) are used, instead of such a separation plate 400 as in the embodiment described above. The separation plates 700a to 700c are each disposed in the space between nozzles 249a and 249b and a boat 217, in substantially parallel to wafers 200.

The separation plates 700a to 700c are fixed to props 304a to 304c, respectively. Gas supply holes 250a and 250b are each disposed corresponding to the position of the wafer 200 between such separation plates 700a, 700b, or 700c. As above, since the separation plates serving as divisions are disposed near the props where a downward flow of gas occurs easily, a downward flow of gas is inhibited, leading to efficient gas supply to each wafer 200. In the present Modified Example 4, the separation plates 700a to 700c disposed as divisions are low in internal stress and thus are not easily damaged. The separation plates 700a to 700c can be made thin, leading to easy production. Note that, even in a case where the separation plates 700a to 700c are each a circumferentially divided plate, such as an arc-shaped plate, instead of a crescent-shaped plate, a similar effect can be obtained.

### Modified Example 5

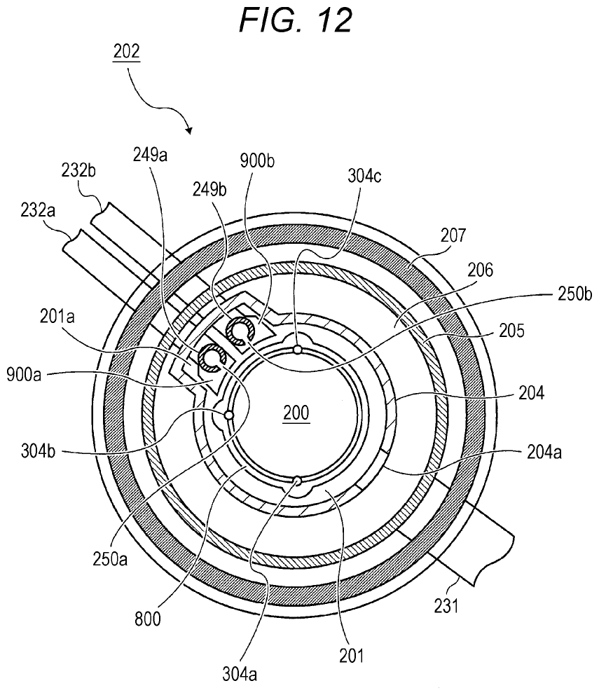

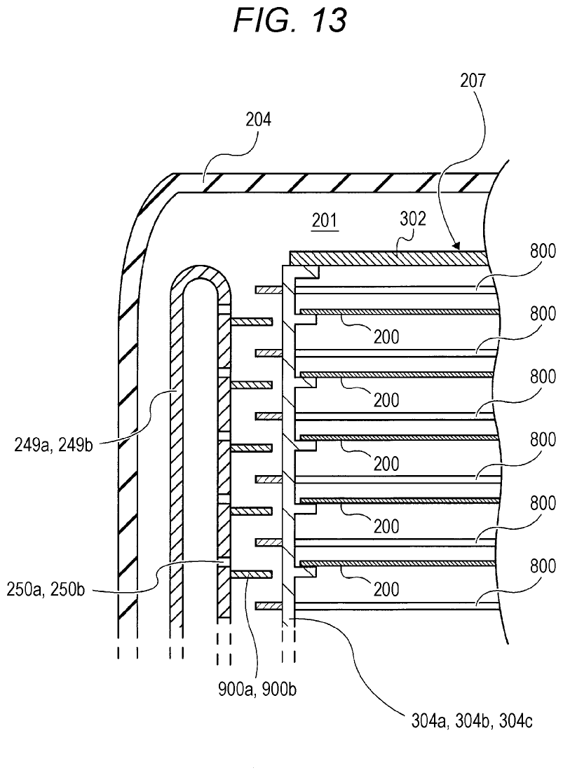

In Modified Example 5, as illustrated in FIGS. 12 and 13, a reaction tube 203 includes an outer tube 205 and an inner tube 204. The respective vertical portions of nozzles 249a and 249b are provided inside a supply chamber 201a being channel-shaped (groove shaped), protruding outward in the radial direction of the inner tube 204, and extending in the vertical direction. Then, in a process chamber 201, provided are movable separation plates 800 each fixed to props 304a to 304c, fixed separation plates 900a fixed to the nozzle 249a in the supply chamber 201a, and fixed separation plates 900b fixed to the nozzle 249b in the supply chamber 201a.

The movable separation plates 800 are each an annular flat plate protruding in a crescent shape near the props 304a to 304c such that its width (outer diameter) is wider (larger) near the props 304a to 304c than at the others, as illustrated in FIG. 12. The movable separation plates 800 each have its inner diameter larger than the outer diameter of a wafer 200 and are each fixed substantially perpendicularly to the outer circumferential side of each of the props 304a to 304c. That is, the movable separation plates 800 are disposed between the nozzles 249a and 249b and a boat 217 and are fixed rotatably between the nozzles 249a and 249b and the boat 217. The movable separation plates 800 each include, on its outer circumferential side, a narrow-width portion or cut-away portion enabling passage with avoidance of the fixed separation plates 900a and 900b described later at the time of loading of the boat 217 into the inner tube 204. In the present example, the portion excluding the crescent-shaped protrusions corresponds to the narrow-width portion, that is, the narrow-width portion or cut-away portion is formed around the props 304b to 304c.

As illustrated in FIGS. 12 and 13, the fixed separation plates 900a are fixed substantially perpendicularly to the nozzle 249a serving as a gas supplier and the fixed separation plates 900b are fixed substantially perpendicularly to the nozzle 249b serving as a gas supplier. The fixed separation plates 900a and 900b are disposed between the nozzles 249a and 249b and the boat 217 and are fixed unrotatably between the nozzles 249a and 249b and the boat 217. Note that the fixed separation plates 900a and 900b may be each fixed to the reaction tube 203. As above, the provision of the fixed separation plates 900a and 900b fixed unrotatably in the process chamber 201 enables inhibition of a downward flow of gas immediately after supply from gas supply holes 250a and 250b.

As illustrated in FIG. 13, the gas supply holes 250a and 250b are each disposed between movable separation plates 800. The gas supply holes 250a are each disposed just above the corresponding fixed separation plate 900a, and the gas supply holes 250b are each disposed just above the corresponding fixed separation plate 900b. That is, each gas supply hole 250a and the corresponding fixed separation plate 900a are disposed between movable separation plates 800, and each gas supply hole 250b and the corresponding fixed separation plate 900b are disposed between movable separation plates 800. The fixed separation plates 900a and 900b extend toward the center of the inner tube 204 with respect to the inner circumferential face of the inner tube 204 and are disposed in substantially parallel to the movable separation plates 800 and wafers 200. The gas supply holes 250a and 250b are each formed corresponding to the position of a wafer 200. That is, the movable separation plates 800 and the fixed separation plates 900a and 900b are each disposed between the nozzles 249a and 249b and the boat 217. According to such a configuration, the gas discharged from each of the gas supply holes 250a and 250b flows along the corresponding fixed separation plate 900a or 900b and then almost all the gas travels straight to flow onto the surface of the corresponding wafer 200. In a case where the gas supply holes 250a and 250b are each opposed to (face) any of the props 304a to 304c, the gas having hit against the props 304a to 304c is rectified to a horizontal flow around the props 304a to 304c because the corresponding movable separation plate 800 restricts a downward flow of gas. Thus, efficient gas supply can be made to each wafer 200.

As illustrated in FIG. 13, the movable separation plates 800 are each disposed, between the upper adjacent wafer 200 and the lower adjacent wafer 200, closer to the lower adjacent wafer 200 in height than to the upper adjacent wafer 200. That is, the distance between each movable separation plate 800 and the lower adjacent wafer 200 is shorter than the distance between each movable separation plate 800 and the upper adjacent wafer 200. Thus, below each wafer 200, secured is a space for lifting and conveying the wafer 200. That is, an adequate interval between a wafer 200 and the movable separation plate 800 below the wafer 200 enables use of a lifting transferer.

### Modified Example 6

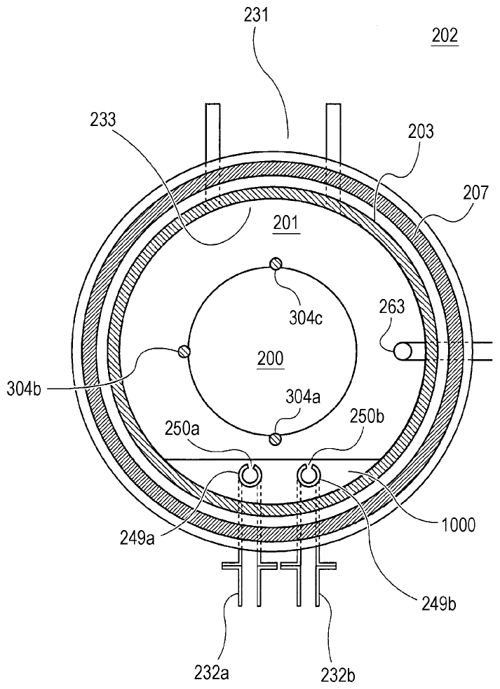

In Modified Example 6, as a separation plate, as illustrated in FIG. 14, a fixed separation plate 1000 fixed in a reaction tube 203 is used, instead of such a separation plate 400 as in the embodiment described above.

That is, the fixed separation plate 1000 fixed in the reaction tube 203 is provided near nozzles 249a and 249b. The fixed separation plate 1000 has through-holes for the nozzles 249a and 249b, in which the nozzles 249a and 249b are provided one-to-one through the through-holes. Such a plurality of fixed separation plates 1000 is provided in a substantially vertical direction in the reaction tube 203, in which each fixed separation plate 1000 is substantially horizontal. The fixed separation plates 1000 are each disposed between gas supply holes 250a of the nozzle 249a and between gas supply holes 250b of the nozzle 249b. That is, the gas supply holes 250a and 250b are each disposed between fixed separation plates 1000. The fixed separation plates 1000 each have a part disposed between the nozzles 249a and 249b and a boat 217 and are each fixed unrotatably between the nozzles 249a and 249b and the boat 217. According to such a configuration, an effect similar to that in the embodiment described above is obtained.

### Other Embodiments

Various exemplary embodiments and modified examples of the present disclosure have been described above, but the present disclosure is not limited to such embodiments. Thus, any appropriate combination thereof can be provided.

For example, the configuration in which the inner diameter of a separation plate 400 is not more than the outer diameter of a wafer 200 has been given in the embodiment described above, but this is not limiting. Thus, the inner diameter of a separation plate 400 may be larger than the outer diameter of a wafer 200. That is, such a separation plate 400 may be fixed to the props 304a to 304c without being penetrated by the props 304a to 304c.

The example in which a wafer 200 is placed on support pins 221 has been given in the embodiment described above, but this is not limiting. Thus, a wafer 200 may be placed with the respective support grooves formed on the props 304a to 304c or a wafer 200 may be placed on a separation plate.

Note that particular embodiments and modified examples of the present disclosure have been described in detail, but the present disclosure is not limited to such embodiments and modified examples. Thus, it is obvious to those skilled in the art that other various embodiments can be made without departing from the scope of the present disclosure.

According to the present disclosure, an improvement can be made in the efficiency of supply of processing gas with constancy or improvement in in-plane uniformity.

What is claimed is:

1. A substrate processing apparatus comprising:
a substrate holder that holds a plurality of substrates;
a reaction tube that houses the substrate holder;
a gas supplier that has a plurality of supply holes corresponding one-to-one to the plurality of substrates and supplies gas to the plurality of substrates; and
a plurality of plates provided in substantially parallel to the plurality of substrates, wherein:
at least part of each of the plurality of plates is disposed between the gas supplier and the substrate holder.

2. The substrate processing apparatus according to claim 1, wherein each of the plurality of plates is annular in shape.

3. The substrate processing apparatus according to claim 1, wherein each of the plurality of plates includes one or more crescent-shaped or arch-shaped plates.

4. The substrate processing apparatus according to claim 1, wherein each of the plurality of plates is disposed closer to an upper adjacent substrate in height than to a lower adjacent substrate among the plurality of substrates.

5. The substrate processing apparatus according to claim 1, wherein the plurality of plates includes a plurality of plates large in diameter and a plurality of plates small in diameter disposed alternately, and
the plurality of substrates is disposed directly above the plurality of plates small in diameter.

6. The substrate processing apparatus according to claim 1, wherein:
the substrate holder includes a plurality of props, and
each of the plurality of plates is fixed to the plurality of props.

7. The substrate processing apparatus according to claim 1, wherein each of the plurality of plates is fixed between the gas supplier and the substrate holder.

8. The substrate processing apparatus according to claim 1, wherein the substrate holder includes a plurality of props of which respective central axes are located inward by an amount equivalent to a diameter of each of the plurality of props from an outer circumference of each of the plurality of plates and are located outside an inner circumference of each of the plurality of plates.

9. The substrate processing apparatus according to claim 1, wherein each of the plurality of supply holes is directed obliquely downward.

10. The substrate processing apparatus according to claim 1, wherein each of the plurality of plates includes an outer circumferential portion that is disposed between the gas supplier and the substrate holder and is directed obliquely upward.

11. The substrate processing apparatus according to claim 1, wherein each of the plurality of plates is fixed to the gas supplier.

12. The substrate processing apparatus according to claim 1, wherein, in horizontal sectional view, a width of each of the plurality of plates occupying between the gas supplier and a circle corresponding to a radius of gyration of the substrate holder is larger than a width of a prop of the substrate holder or a distance between the circle and an end portion of each of the plurality of substrates.

13. The substrate processing apparatus according to claim 1, wherein each of the plurality of plates is disposed closer to a lower adjacent substrate in height than to an upper adjacent substrate among the plurality of substrates.

14. The substrate processing apparatus according to claim 1, wherein:
the substrate holder includes a plurality of props,
each of the plurality of plates includes a movable plate fixed to the plurality of props and a fixed plate fixed to the gas supplier or the reaction tube, and
the movable plate includes a narrow-width portion or cut-away portion enabling passage with avoidance of the fixed plate when the substrate holder is loaded into the reaction tube.

15. The substrate processing apparatus according to claim 1, wherein:
the substrate holder includes a plurality of props, and
each of the plurality of plates has a width widening near the plurality of props.

16. A substrate holder comprising:
a plurality of props;
a plurality of supports that extends inward from the plurality of props and bears a plurality of substrates; and
a plurality of plates each fixed to the plurality of props in substantially parallel to the plurality of substrates, wherein
at least part of each of the plurality of plates is disposed outside a circle corresponding to a radius of gyration of the plurality of props.

17. A method of manufacturing a semiconductor device, the method comprising:
housing a plurality of substrates held by a substrate holder into a reaction tube;
supplying gas to the plurality of substrates by a gas supplier having a plurality of supply holes corresponding one-to-one to the plurality of substrates, with the gas supplier and the substrate holder between which at least part of each of a plurality of plates disposed in substantially parallel to the plurality of substrates is provided; and
exhausting the gas supplied to the plurality of substrates.

18. A non-transitory computer-readable recording medium storing a program that causes, by a computer, a substrate processing apparatus to perform a process comprising a method manufacturing a semiconductor device, the method comprising:
housing a plurality of substrates held by a substrate holder into a reaction tube;
supplying gas to the plurality of substrates by a gas supplier having a plurality of supply holes corresponding one-to-one to the plurality of substrates, with the gas supplier and the substrate holder between which at least part of each of a plurality of plates disposed in substantially parallel to the plurality of substrates is provided; and
exhausting the gas supplied to the plurality of substrates.
